(19) United States
(12) Patent Application Publication
(10) Pub. No.: US 2026/0156864 A1
(43) Pub. Date: Jun. 4, 2026

(54) TRANSISTOR STRUCTURE AND MANUFACTURING METHOD THEREOF

(71) Applicant: United Microelectronics Corp., Hsinchu (TW)

(72) Inventors: Hao Ping Yan, Tainan City (TW); Wei Hsuan Chang, Tainan City (TW); Chin-Chia Kuo, Tainan City (TW); Ming-Hua Tsai, Tainan City (TW)

(73) Assignee: United Microelectronics Corp., Hsinchu (TW)

(21) Appl. No.: 18/956,006

(22) Filed: Nov. 22, 2024

(30) Foreign Application Priority Data
Oct. 22, 2024 (TW) 113140190

(51) Int. Cl. H10D 30/67; H10D 30/01; H10D 62/10; H10D 62/60; H10D 64/01; H10D 64/27; H10D 64/66

(52) U.S. Cl. CPC H10D 30/6721; H10D 30/0229; H10D 30/6719; H10D 62/124; H10D 62/60; H10D 64/021; H10D 64/516; H10D 64/675; H10D 62/102

(57) ABSTRACT

Provided are a transistor structure and a manufacturing method thereof. The transistor structure includes a gate dielectric layer, a gate disposed on the gate dielectric layer, a spacer structure located on the gate dielectric layer and disposed on the sidewall of the gate, first, second and third doped regions, and a metal silicide layer. The first doped regions are disposed in the substrate on two sides of the gate. The second doped regions are disposed in the first doped regions, respectively. The third doped regions is disposed in the second doped regions, respectively. The metal silicide layer is disposed at the surface of the third doped regions. In the channel direction, the first doped regions extend below the gate to partially overlap with the gate, the second doped regions extends below the spacer structure, and the metal silicide layer does not extend below the gate.

### CROSS-REFERENCE TO RELATED APPLICATION

This application claims the priority benefit of Taiwan application serial no. 113140190, filed on Oct. 22, 2024. The entirety of the above-mentioned patent application is hereby incorporated by reference herein and made a part of this specification.

### BACKGROUND

### Technical Field

The present invention relates to a semiconductor structure and a manufacturing method thereof, and in particular, to a transistor structure and a manufacturing method thereof.

### Description of Related Art

In the current metal-oxide-semiconductor (MOS) transistor process, after forming the gate and the spacer located on the sidewall of the gate, the gate dielectric layer on both sides of the gate is removed to expose the source region and the drain region in the substrate on both sides, and then a metal silicide process is performed to form a metal silicide layer at the source region and the drain region.

For the transistor requiring a higher operating voltage, such as the medium-voltage transistor or the high-voltage transistor, a thicker gate dielectric layer is required. Therefore, when removing the gate dielectric layer on both sides of the gate to expose the source region and the drain region, a longer etching time is required, and the longer etching time may cause the gate dielectric layer under the gate to be subjected to excessive lateral etching, and thus a recess is formed. In this way, after the metal silicide process, in addition to being formed on the source region and the drain region, the metal silicide layer may extend below the gate through the recess of the gate dielectric layer, thus seriously affecting the electrical properties of the formed transistor.

### SUMMARY

The present invention provides a transistor structure and a manufacturing method thereof, wherein the gate dielectric layer may have a larger thickness so that the contact may be electrically connected to the gate directly above the channel region.

The invention provides a manufacturing method of a transistor structure, wherein the gate dielectric layer may have greater thickness, and the metal silicide layer may not extend below the gate.

The transistor structure of the present invention includes a gate dielectric layer, a gate, a spacer structure, first doped regions, second doped regions, third doped regions, and a metal silicide layer. The gate dielectric layer is disposed on a substrate. The gate is disposed on the gate dielectric layer. The spacer structure is located on the gate dielectric layer and disposed on a sidewall of the gate. The first doped regions are disposed in the substrate on both sides of the gate. The second doped regions are disposed in the first doped regions, respectively. The third doped regions are disposed in the second doped regions, respectively. The metal silicide layer is disposed at surfaces of the third doped regions. In a channel direction of the transistor structure, the first doped regions extend below the gate to partially overlap with the gate, the second doped regions extend below the spacer structure to partially overlap with the spacer structure, and the metal silicide layer does not extend below the gate.

In an embodiment of the transistor structure of the present invention, in the channel direction, the metal silicide layer does not extend beyond a boundary between the second doped region and the first doped region.

In an embodiment of the transistor structure of the present invention, the first doped regions, the second doped regions and the third doped regions have a same conductive type.

In an embodiment of the transistor structure of the present invention, an atom size of a dopant in the second doped regions is larger than an atom size of a dopant in the first doped regions.

In an embodiment of the transistor structure of the present invention, a dopant in the third doped regions is the same as a dopant in the second doped regions.

In an embodiment of the transistor structure of the present invention, a doping concentration of the third doped regions is greater than a doping concentration of the second doped regions, and the doping concentration of the second doped regions is greater than a doping concentration of the first doped regions.

In an embodiment of the transistor structure of the present invention, a thickness of the gate dielectric layer is not less than 160 Å.

In an embodiment of the transistor structure of the present invention, the spacer structure includes a first spacer, a second spacer and a third spacer located in sequence on the sidewall of the gate.

In an embodiment of the transistor structure of the present invention, a material of the first spacer and a material of the third spacer include silicon nitride, and a material of the second spacer includes silicon oxide.

In an embodiment of the transistor structure of the present invention, the gate dielectric layer has a uniform thickness, the first spacer, the second spacer and the third spacer are only located on the gate dielectric layer, and the second spacer extends between the third spacer and the gate dielectric layer.

In an embodiment of the transistor structure of the present invention, the gate dielectric layer includes a first portion with a larger thickness and a second portion with a smaller thickness, the gate and the first spacer are located on the first portion, the second spacer and the third spacer are located on the second portion, and the second spacer extends between the third spacer and the second portion.

In an embodiment of the transistor structure of the present invention, a boundary of the second doped region adjacent to the gate is aligned with a boundary between the first spacer and the second spacer.

In an embodiment of the transistor structure of the present invention, a boundary of the third doped region adjacent to the gate is aligned with an outer sidewall of the spacer structure.

In an embodiment of the transistor structure of the present invention, further includes a contact electrically connected to the gate directly above a channel region of the transistor structure.

The manufacturing method of the transistor structure of the present invention includes the following steps. A gate dielectric layer is formed on a substrate. A gate is formed on the gate dielectric layer. A spacer structure is formed on a sidewall of the gate, wherein the spacer structure is located on the gate dielectric layer. First doped regions are formed in the substrate on both sides of the gate. Second doped regions are formed in the first doped regions, respectively. Third doped regions are formed in the second doped regions, respectively. A metal silicide layer is formed at surfaces of the third doped regions. In a channel direction of the transistor structure, the first doped regions extend below the gate to partially overlap with the gate, the second doped regions extend below the spacer structure to partially overlap with the spacer structure, and the metal silicide layer does not extend below the gate.

In an embodiment of the manufacturing method of the transistor structure of the present invention, in the channel direction, the metal silicide layer does not extend beyond a boundary between the second doped region and the first doped region.

In an embodiment of the manufacturing method of the transistor structure of the present invention, the first doped regions, the second doped regions and the third doped regions have a same conductive type.

In an embodiment of the manufacturing method of the transistor structure of the present invention, an atom size of a dopant in the second doped regions is larger than an atom size of a dopant in the first doped regions.

In an embodiment of the manufacturing method of the transistor structure of the present invention, a dopant in the third doped regions is the same as a dopant in the second doped regions.

In an embodiment of the manufacturing method of the transistor structure of the present invention, a doping concentration of the third doped regions is greater than a doping concentration of the second doped regions, and the doping concentration of the second doped regions is greater than a doping concentration of the first doped regions.

In an embodiment of the manufacturing method of the transistor structure of the present invention, a thickness of the gate dielectric layer is not less than 160 Å.

In an embodiment of the manufacturing method of the transistor structure of the present invention, a forming method of the gate dielectric layer, the gate, the spacer structure, the second doped regions and the third doped regions includes the following steps. A gate dielectric material layer and a gate material layer are formed sequentially on the substrate, wherein first doped regions are formed in the substrate. The gate material layer is patterned to form the gate. A first spacer material layer is conformally formed on the substrate. A first anisotropic etching process is performed to remove a part of the first spacer material layer to form a first spacer. A part of the gate dielectric material layer on both sides of the gate is removed. A first ion implantation process is performed to form the second doped regions. A second spacer material layer is conformally formed on the substrate. A third spacer material layer is conformally formed on the second spacer material layer. A second anisotropic etching process is performed to remove a part of the third spacer material layer to form a third spacer. A second ion implantation process is performed to form the third doped regions. The gate dielectric material layer and the second spacer material layer on a top surface of the gate and on the third doped regions are removed to form a second spacer between the first spacer and the third spacer. The first spacer, the second spacer and the third spacer constitute the spacer structure.

In an embodiment of the manufacturing method of the transistor structure of the present invention, after removing the part of the gate dielectric material layer on both sides of the gate, the gate dielectric material layer includes a first portion with a larger thickness and a second portion with a smaller thickness, and the gate and the spacer structure is located on the first portion.

In an embodiment of the manufacturing method of the transistor structure of the present invention, after removing the part of the gate dielectric material layer on both sides of the gate, the gate dielectric material layer includes a first portion with a larger thickness and a second portion with a smaller thickness, the gate and the first spacer is located on the first portion, and the second spacer and the third spacer are located on the second portion.

In an embodiment of the manufacturing method of the transistor structure of the present invention, the method further includes forming a contact electrically connected to the gate directly above a channel region of the transistor structure after forming the metal silicide layer.

Based on the above, in the transistor structure and the manufacturing method thereof of the present invention, since the second doped region is formed in the first doped region, and the atom size of the dopant in the second doped region is larger than the atom size of the dopant in the first doped region, it may effectively prevent the metal silicide layer from extending into the first doped region and causing the leakage current. In this way, the gate dielectric layer may have a greater thickness, and therefore the subsequently formed contact may be electrically connected to the gate directly above the channel region.

### BRIEF DESCRIPTION OF THE DRAWINGS

FIGS. 1A to 1F are schematic cross-sectional views of the manufacturing process of the transistor structure of the first embodiment of the present invention.

FIG. 2 is a schematic cross-sectional view of forming the contact on the gate directly above the channel region of the transistor structure in FIG. 1F.

FIGS. 3A to 3C are schematic cross-sectional views of the manufacturing process of the transistor structure of the second embodiment of the present invention.

### DESCRIPTION OF THE EMBODIMENTS

The embodiments are listed below and described in detail with the accompanying drawings, but the provided embodiments are not intended to limit the scope of the present invention. In addition, the drawings are for illustration purposes only and are not drawn to original scale. In order to facilitate understanding, the same devices will be described with the same symbols in the following descriptions.

In the text, the terms mentioned in the text, such as “comprising”, “including”, “containing” and “having” are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the present invention.

In addition, the directional terms, such as “on”, “above”, “under” and “below” mentioned in the text are only used to refer to the direction of the drawings, and are not used to limit the present invention. Therefore, it should be understood that “on” may be used interchangeably with “under”. When a device such as a layer or a film is placed “on” another device, the device may be placed directly on the other device, or an intermediate device may be present. On the other hand, when a device is placed “directly on” another device, there is no intermediate device between the two.

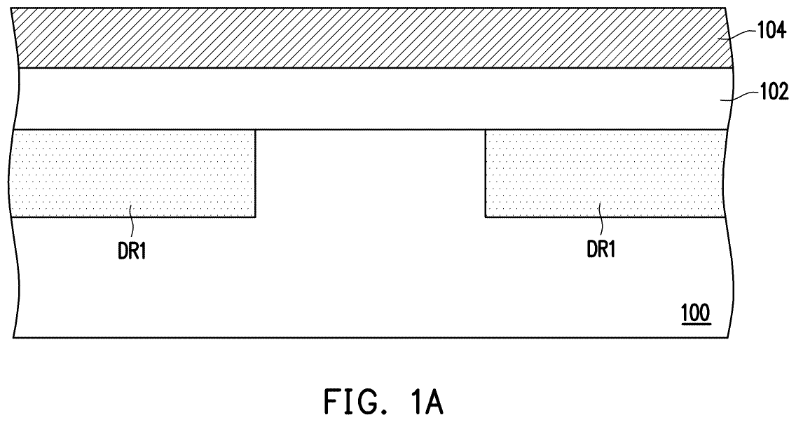

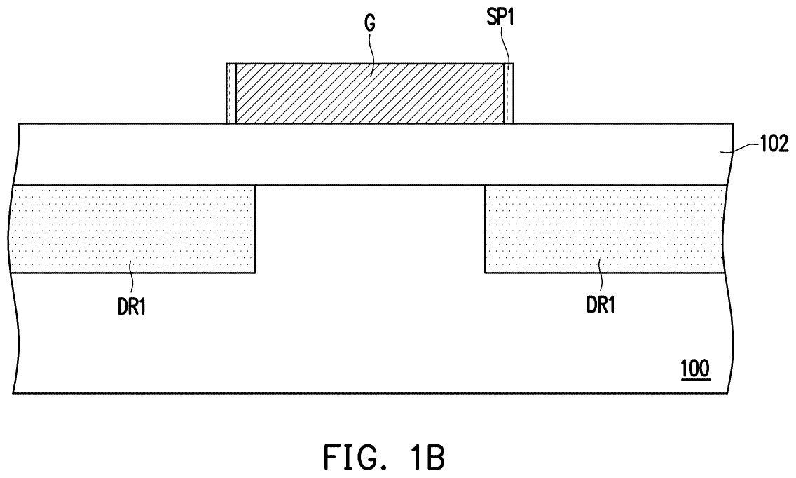

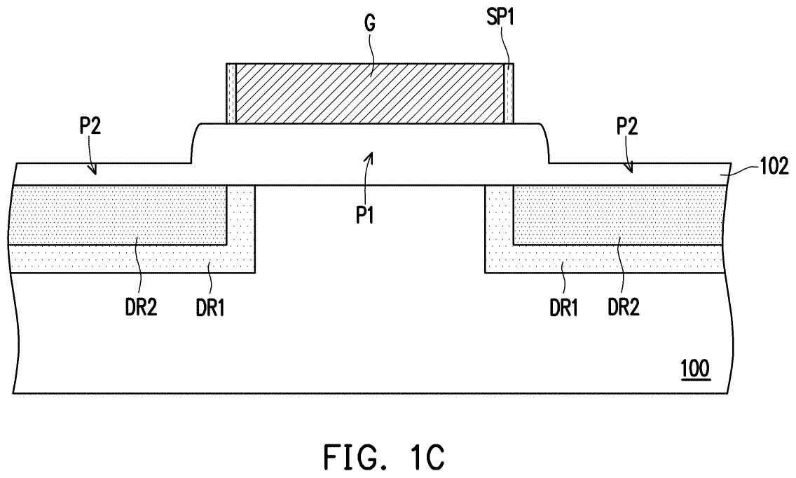

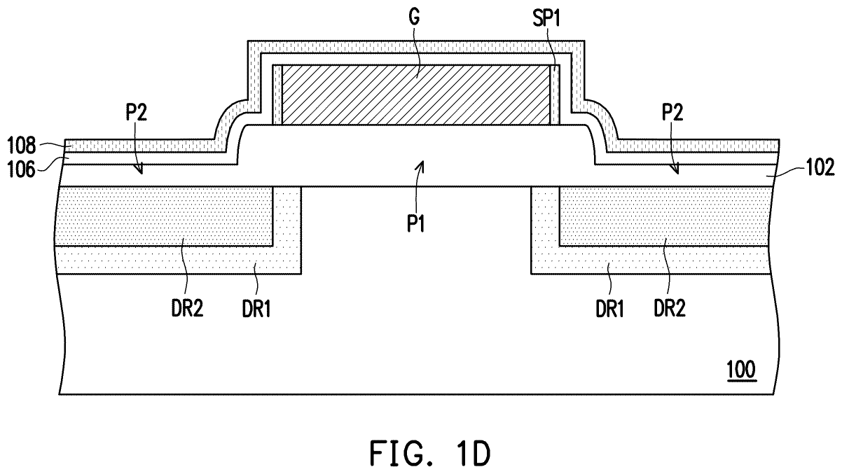

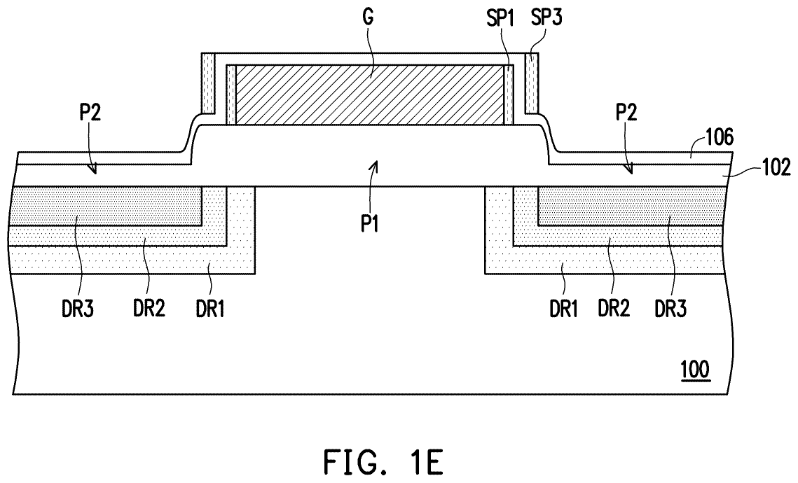

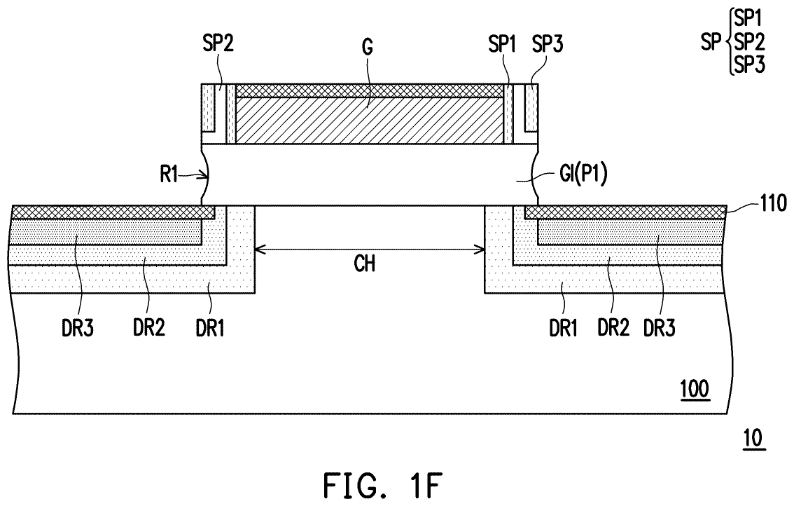

FIGS. 1A to 1F are schematic cross-sectional views of the manufacturing process of the transistor structure of the first embodiment of the present invention.

Referring to FIG. 1A, a substrate 100 is provided. In the present embodiment, the substrate 100 may be a silicon substrate. Then, first doped regions DR1 are formed in a part of substrate 100. The first doped regions DR1 are located at the surface of the substrate 100. The first doped regions DR1 are formed by, for example, performing an ion implantation process. In the present embodiment, the first doped regions DR1 are used as the lightly doped drain (LDD) of the transistor structure. Therefore, there is a distance between adjacent first doped regions DR1 to form a channel region of the transistor structure. Depending on the type of transistor structure to be formed, the conductive type of the first doped region DR1 may be N-type or P-type.

After the first doped regions DR1 are formed, a gate dielectric material layer 102 and a gate material layer 104 are sequentially formed on the substrate 100. The gate dielectric material layer 102 may be a silicon oxide layer. The gate dielectric material layer 102 is formed by, for example, performing a thermal oxidation process. In the present embodiment, the thickness of the gate dielectric material layer 102 is not less than 160 Å, so that the transistor structure of the present embodiment may be used in not only a low-voltage transistor, but also a medium-voltage transistor and a high-voltage transistor. The gate material layer 104 may be a polysilicon layer. The gate material layer 104 is formed by, for example, performing a chemical vapor deposition (CVD) process.

Referring to FIG. 1B, the gate material layer 104 is patterned to form a gate G. In the present embodiment, the gate G partially overlaps with the first doped regions DR1. In other words, the first doped regions DR1 are located in the substrate 100 on both sides of the gate G, and extend below the gate G to partially overlap with the gate G.

After the gate G is formed, a first spacer SP1 is formed on the sidewall of the gate G. In the present embodiment, the material of the first spacer SP1 is silicon nitride, for example. The forming method of the first spacer SP1 may include the following steps. First, a first spacer material layer is conformally formed on the substrate 100. After that, an anisotropic etching process is performed to remove a part of the first spacer material layer until the top surface of the gate G and the top surface of the gate dielectric material layer 102 are exposed.

Referring to FIG. 1C, a part of the gate dielectric material layer 102 on both sides of the gate G is removed. In the present embodiment, after removing the part of the gate dielectric material layer 102 on both sides of the gate G, the gate dielectric material layer 102 includes a first portion P1 with a larger thickness and a second portion P2 with a smaller thickness. At this time, the gate G and the first spacer SP1 are located on the first portion P1, and the first portion P1 extends outward from the outer sidewall of the first spacer SP1 for a certain distance. The second portion P2 with the smaller thickness is beneficial to the subsequent ion implantation process performed on the substrate 100.

After that, an ion implantation process is performed to form second doped regions DR2 in the first doped regions DR1, respectively. In the present embodiment, during the ion implantation process, the gate G and the first spacer SP1 are used as a mask, so the formed second doped regions DR2 are located in the first doped regions DR1, and the boundary of the second doped region DR2 adjacent to the gate G is aligned with the outer sidewall of the first spacer SP1. In addition, the bottom surface of the second doped region DR2 is higher than the bottom surface of the first doped region DR1. The second doped regions DR2 are used as the LDD of the transistor structure. Therefore, the first doped regions DR1 and the second doped regions DR2 have the same conductive type.

In the present embodiment, the first doped regions DR1 and the second doped regions DR2 have the same conductive type, and the atom size of the dopant in the second doped regions DR2 is larger than the atom size of the dopant in the first doped regions DR1. For example, when the first doped regions DR1 and the second doped regions DR2 are N-type, the dopant in the first doped regions DR1 may include phosphorus (P), and the dopant in the second doped regions DR2 may include arsenic (As). When the first doped regions DR1 and the second doped regions DR2 are P-type, the dopant in the first doped regions DR1 may include boron (B), and the dopant in the second doped regions DR2 may include gallium (Ga) or indium (In). In addition, in the present embodiment, the doping concentration of the second doped regions DR2 is greater than the doping concentration of the first doped regions D1.

Referring to FIG. 1D, a second spacer material layer 106 is formed conformally on the substrate 100. The material of the second spacer material layer 106 is, for example, silicon oxide. After the second spacer material layer 106 is formed, a third spacer material layer 108 is conformally formed on the second spacer material layer 106. The material of third spacer material layer 108 is silicon nitride, for example. At this time, a part of the second spacer material layer 106 and a part of the third spacer material layer 108 are located on the first portion P1 of gate dielectric material layer 102 and cover the gate G and the first spacer SP1, while the remaining second spacer material layer 106 and the remaining third spacer material layer 108 are located on the second portion P2 of the gate dielectric material layer 102.

Referring to FIG. 1E, an anisotropic etching process is performed to remove a part of the third spacer material layer 108 until the second spacer material layer 106 is exposed. The remaining third spacer material layer 108 forms a third spacer SP3 located outside the first spacer SP1, and a part of the second spacer material layer 106 is located between the first spacer SP1 and the third spacer SP3. The third spacer SP3 is located on the first portion P1 of the gate dielectric material layer 102.

During the above anisotropic etching process, in addition to removing a part of the third spacer material layer 108, the second spacer material layer 106 below the third spacer material layer 108 may also be slightly removed. As a result, after the above anisotropic etching process, the second spacer material layer 106 located on the sidewall of the first portion P1 of the gate dielectric material layer 102 is slightly removed and may have a concave surface.

After that, an ion implantation process is performed to form third doped regions DR3 in the second doped regions DR2, respectively. In the present embodiment, during the ion implantation process, the gate G, the first spacer SP1, the third spacer SP3 and the second spacer material layer 106 therebetween are used as a mask, so the formed third doped regions DR3 are located in the second doped regions DR2, and the boundary of third doped region DR3 adjacent to the gate G is aligned with the outer sidewall of the third spacer SP3. In addition, the bottom surface of the third doped region DR3 is higher than the bottom surface of the second doped region DR2. The third doped regions DR3 are used as the source and the drain of the transistor structure. Therefore, the third doped regions DR3 have the same conductive type as the first doped regions DR1 and the second doped regions DR2.

In the present embodiment, the dopant in the third doped regions DR3 is the same as the dopant in the second doped regions DR2, and the doping concentration of the third doped regions DR3 is greater than the doping concentration of the second doped regions DR2. That is, in the present embodiment, from the third doped regions DR3 to the first doped regions DR1, the concentrations of the dopants with the same conductive type may be decreased in a gradient manner. In this way, the off-current (I_{off}) of the transistor may be effectively improved.

Referring to FIG. 1F, an etching process is performed to remove the second spacer material layer 106 on the top surface of the gate G and on the third doped regions DR3, and to remove the second portion P2 of the gate dielectric material layer 102. During the etching process, the third spacer SP3 may also be slightly removed. In this way, the second spacer material layer 106 located between the first spacer SP1 and the third spacer SP3 forms the second spacer SP2, and the second spacer SP2 extends below the third spacer SP3. The top surface of the first spacer SP1, the top surface of the second spacer SP2 and the top surface of the third spacer SP3 may be coplanar with the top surface of the gate G. The first spacer SP1, the second spacer SP2 and the third spacer SP3 constitute the spacer structure SP located on the sidewall of the gate G. In addition, the first portion P1 of the gate dielectric material layer 102 forms a gate dielectric layer GI of the transistor structure, so that the gate dielectric layer GI has a uniform and larger thickness (not less than 160 Å). Therefore, in the present embodiment, the entire spacer structure SP is only located on the gate dielectric layer GI, and the second doped regions DR2 partially overlap with the spacer structure SP.

In addition, in the present embodiment, since the gate dielectric material layer 102 formed in the steps described in FIG. 1A has a larger thickness (not less than 160 Å), in order to completely remove the second spacer material layer 106 and the second portion P2 of the gate dielectric material layer 102 above the third doped regions DR3, a longer etching time may be required. Therefore, the gate dielectric layer GI may inevitably be laterally etched, and thus a recess R1 is formed at the sidewall of the gate dielectric layer GI.

After that, a metal silicide process is performed to form a metal silicide layer 110 at the surface of the third doped regions DR3 and the top surface of the gate G. In this way, the transistor structure 10 of the present embodiment is formed.

During the above metal silicide process, since the sidewall of the gate dielectric layer GI has the recess R1, the metal silicide layer 110 formed at the surface of the third doped regions DR3 easily extends below the gate dielectric layer GI through the recess R1. In the present embodiment, since the second doped regions DR2 are formed in the first doped regions DR1 and the atom size of the dopant in the second doped regions DR2 is larger than the atom size of the dopant in the first doped regions DR1, it can effectively prevent the metal silicide layer 110 from further extending into the first doped regions DR1 and causing leakage current in the transistor during the operation.

Furthermore, in the present embodiment, since the dopant in the third doped regions DR3 is the same as the dopant in the second doped regions DR2 and the atom size of the dopant in the second doped regions DR2 is larger than the atom size of the dopant in the first doped regions DR1, the metal silicide layer 110 is formed at the surface of the third doped regions DR3, and may be formed at the surface of the second doped regions DR2 through the recess R1 of the gate dielectric layer GI, but cannot extend into the first doped regions DR1. That is, in the channel direction of the channel region CH of the transistor structure 10, the metal silicide layer 110 does not extend beyond the boundary between the second doped region DR2 and the first doped region DR1, and therefore does not extend below the gate G.

On the other hand, in the transistor structure 10 of the present embodiment, since the second doped regions DR2 are located in the first doped regions DR1 and the atom size of the dopant in the second doped region DR2 is larger than the atom size of the dopant in the first doped region DR1, even if the gate dielectric layer GI (the first portion P1 of the gate dielectric material layer 102) has a larger thickness (not less than 160 Å), the metal silicide layer 110 may not extend below the gate G, and thus the transistor structure 10 may be applied not only to the low-voltage transistor, but also to the medium-voltage transistor and the high-voltage transistor.

In addition, for the transistor structure 10 of the present embodiment, since the gate dielectric layer GI has a larger thickness (not less than 160 Å), the subsequently formed contact electrically connected to the gate G may be formed directly above the channel region CH.

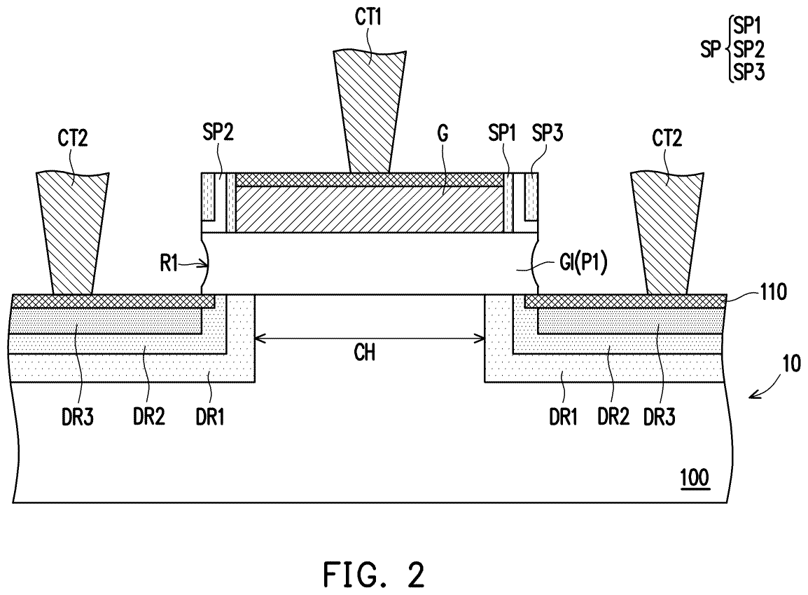

As shown in FIG. 2, after the transistor structure 10 is formed, subsequent processes may be performed to form a contact CT1 electrically connected to the gate G and contacts CT2 electrically connected to the third doped regions DR3 serving as the source and the drain.

In the present embodiment, the metal silicide layer 110 is formed at the top surface of gate G, so the contact CT1 is connected to the metal silicide layer 110 directly above the channel region CH and is electrically connected to the gate G.

In particular, since the gate dielectric layer GI has a larger thickness (not less than 160 Å), it can avoid damage to the gate dielectric layer GI due to too thin thickness and antenna effect during the formation of the contact CT1. In other words, since the gate dielectric layer GI has a larger thickness (not less than 160 Å), the contact CT1 electrically connected to the gate G may be formed on the gate G directly above the channel region CH.

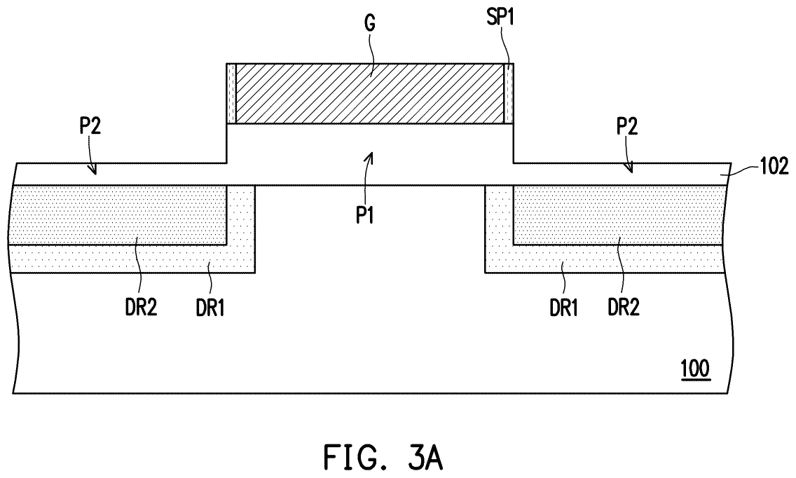

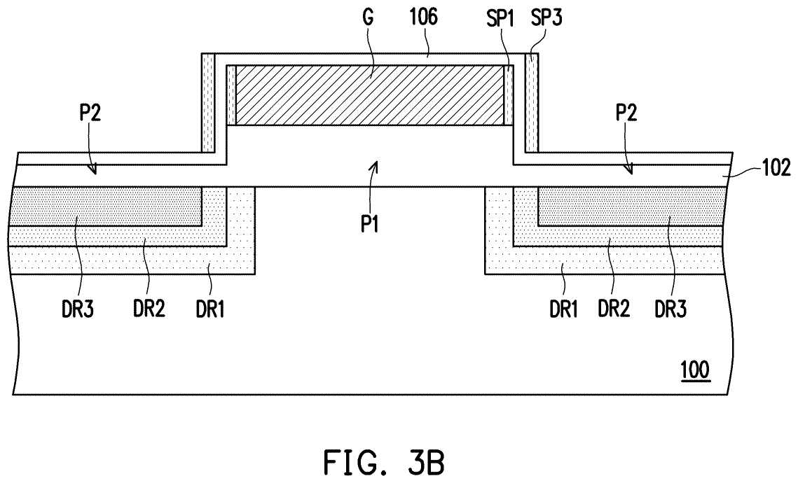

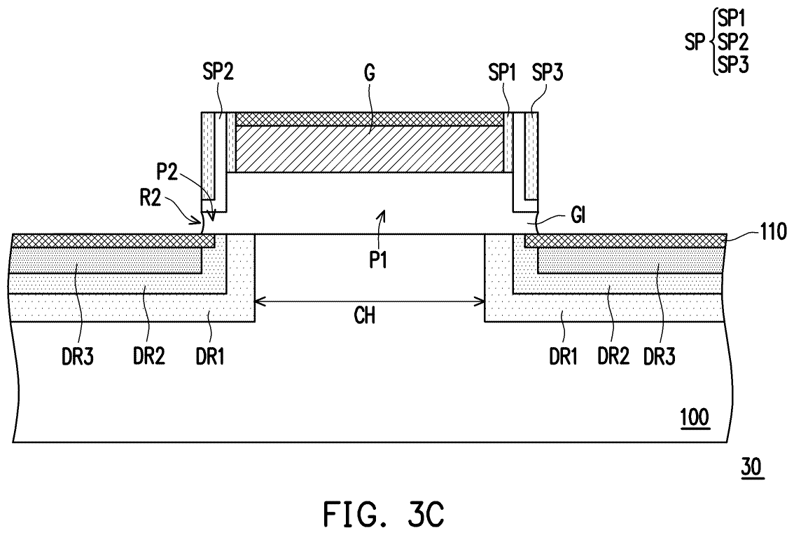

FIGS. 3A to 3C are schematic cross-sectional views of the manufacturing process of the transistor structure of the second embodiment of the present invention. In the present embodiment, the devices that are the same as those in the first embodiment will be represented by the same reference symbols and will not be described again.

Referring to FIG. 3A, after forming the structure as shown in FIG. 1B, a part of the gate dielectric material layer 102 on both sides of the gate G is removed. In the present embodiment, after removing the part of the gate dielectric material layer 102 on both sides of the gate G, the gate dielectric material layer 102 includes a first portion P1 with a larger thickness and a second portion P2 with a smaller thickness. At this time, the gate G and the first spacer SP1 are located on the first portion P1, and the sidewall of the first portion P1 is aligned with the outer sidewall of the first spacer SP1. After that, the steps described in FIG. 1C are performed to form the second doped regions DR2.

Referring to FIG. 3B, the steps described in FIGS. 1D and 1E are performed to form the second spacer material layer 106 and the third spacer material layer 108, and an anisotropic etching process is performed. In the present embodiment, since the sidewall of the first portion P1 of the gate dielectric material layer 102 is aligned with the outer sidewall of the first spacer SP1, the third spacer SP3 formed after the anisotropic etching process and the second spacer material layer 106 between the first spacer SP1 and the third spacer SP3 may be located on the second portion P2 of the gate dielectric material layer 102, and may not be located on the first portion P1 of the gate dielectric material layer 102.

Referring to FIG. 3C, the steps described in FIG. 1F are performed to form the third doped regions DR3, the second spacer SP2 and the metal silicide layer 110. In this way, the transistor structure 30 of the present embodiment is formed. In the present embodiment, the second portion P2 of the gate dielectric material layer 102 remains below the second spacer SP2 and the third spacer SP3, and the first portion P1 and the second portion P2 constitute the gate dielectric layer GI of the transistor structure 30 of the present embodiment. Therefore, in the transistor structure 30, the gate G and the first spacer SP1 are located on the first portion P1 of the gate dielectric layer GI, and the second spacer SP2 and the third spacer SP3 are located on the second portion P2 of the gate dielectric layer GI.

In addition, after performing the etching process to remove the gate dielectric material layer 102 to expose the top surface of the gate G and the third doped regions DR3, the gate dielectric layer GI may inevitably be laterally etched, and thus a recess R2 is formed at the sidewall of the second portion P2.

Similar to the process of transistor structure 10, during the metal silicide process, since the recess R2 is formed at the sidewall of the second portion P2 of the gate dielectric layer GI, the metal silicide layer 110 formed at the surface of the third doped regions DR3 may extend below the gate dielectric layer GI through the recess R2. Since the second doped regions DR2 are formed in the first doped regions DR1 and the atom size of the dopant in the second doped regions DR2 is larger than the atom size of the dopant in the first doped regions DR1, it can effectively prevent the metal silicide layer 110 from further extending into the first doped regions DR1 and causing leakage current in the transistor during the operation.

In addition, in the transistor structure 30, since the first portion P1 of the gate dielectric layer GI has a larger thickness (not less than 160 Å), it can avoid damage to the gate dielectric layer GI due to too thin thickness and antenna effect during the formation of the contact electrically connected to the gate G. In this way, the contact electrically connected to the gate G may be formed on the gate G directly above the channel region CH.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A transistor structure, comprising:
a gate dielectric layer, disposed on a substrate;
a gate, disposed on the gate dielectric layer;
a spacer structure, located on the gate dielectric layer and disposed on a sidewall of the gate;
first doped regions, disposed in the substrate on both sides of the gate;
second doped regions, disposed in the first doped regions, respectively;
third doped regions, disposed in the second doped regions, respectively; and
a metal silicide layer, disposed at surfaces of the third doped regions,
wherein in a channel direction of the transistor structure,
the first doped regions extend below the gate to partially overlap with the gate,
the second doped regions extend below the spacer structure to partially overlap with the spacer structure, and
the metal silicide layer does not extend below the gate.

2. The transistor structure of claim 1, wherein in the channel direction, the metal silicide layer does not extend beyond a boundary between the second doped region and the first doped region.

3. The transistor structure of claim 1, wherein the first doped regions, the second doped regions and the third doped regions have a same conductive type.

4. The transistor structure of claim 3, wherein an atom size of a dopant in the second doped regions is larger than an atom size of a dopant in the first doped regions.

5. The transistor structure of claim 1, wherein a dopant in the third doped regions is the same as a dopant in the second doped regions.

6. The transistor structure of claim 1, wherein a doping concentration of the third doped regions is greater than a doping concentration of the second doped regions, and the doping concentration of the second doped regions is greater than a doping concentration of the first doped regions.

7. The transistor structure of claim 1, wherein a thickness of the gate dielectric layer is not less than 160 Å.

8. The transistor structure of claim 1, wherein the spacer structure comprises a first spacer, a second spacer and a third spacer located in sequence on the sidewall of the gate.

9. The transistor structure of claim 8, wherein a material of the first spacer and a material of the third spacer comprise silicon nitride, and a material of the second spacer comprises silicon oxide.

10. The transistor structure of claim 8, wherein the gate dielectric layer has a uniform thickness, the first spacer, the second spacer and the third spacer are only located on the gate dielectric layer, and the second spacer extends between the third spacer and the gate dielectric layer.

11. The transistor structure of claim 8, wherein the gate dielectric layer comprises a first portion with a larger thickness and a second portion with a smaller thickness, the gate and the first spacer are located on the first portion, the second spacer and the third spacer are located on the second portion, and the second spacer extends between the third spacer and the second portion.

12. The transistor structure of claim 8, wherein a boundary of the second doped region adjacent to the gate is aligned with a boundary between the first spacer and the second spacer.

13. The transistor structure of claim 1, wherein a boundary of the third doped region adjacent to the gate is aligned with an outer sidewall of the spacer structure.

14. The transistor structure of claim 1, further comprising a contact electrically connected to the gate directly above a channel region of the transistor structure.

15. A manufacturing method of a transistor structure, comprising:
forming a gate dielectric layer on a substrate;
forming a gate on the gate dielectric layer;
forming a spacer structure on a sidewall of the gate, wherein the spacer structure is located on the gate dielectric layer;
forming first doped regions in the substrate on both sides of the gate;
forming second doped regions in the first doped regions, respectively;
forming third doped regions in the second doped regions, respectively; and
forming a metal silicide layer at surfaces of the third doped regions,
wherein in a channel direction of the transistor structure,
the first doped regions extend below the gate to partially overlap with the gate,
the second doped regions extend below the spacer structure to partially overlap with the spacer structure, and
the metal silicide layer does not extend below the gate.

16. The manufacturing method of claim 15, wherein in the channel direction, the metal silicide layer does not extend beyond a boundary between the second doped region and the first doped region.

17. The manufacturing method of claim 15, wherein the first doped regions, the second doped regions and the third doped regions have a same conductive type.

18. The manufacturing method of claim 17, wherein an atom size of a dopant in the second doped regions is larger than an atom size of a dopant in the first doped regions.

19. The manufacturing method of claim 15, wherein a dopant in the third doped regions is the same as a dopant in the second doped regions.

20. The manufacturing method of claim 15, wherein a doping concentration of the third doped regions is greater than a doping concentration of the second doped regions, and the doping concentration of the second doped regions is greater than a doping concentration of the first doped regions.

21. The manufacturing method of claim 15, wherein a thickness of the gate dielectric layer is not less than 160 Å.

22. The manufacturing method of claim 15, wherein a forming method of the gate dielectric layer, the gate, the spacer structure, the second doped regions and the third doped regions comprises:
forming a gate dielectric material layer and a gate material layer sequentially on the substrate, wherein first doped regions are formed in the substrate;
patterning the gate material layer to form the gate;
conformally forming a first spacer material layer on the substrate;
performing a first anisotropic etching process to remove a part of the first spacer material layer to form a first spacer;
removing a part of the gate dielectric material layer on both sides of the gate;
performing a first ion implantation process to form the second doped regions;
conformally forming a second spacer material layer on the substrate;
conformally forming a third spacer material layer on the second spacer material layer;
performing a second anisotropic etching process to remove a part of the third spacer material layer to form a third spacer;
performing a second ion implantation process to form the third doped regions; and
removing the gate dielectric material layer and the second spacer material layer on a top surface of the gate and on the third doped regions to form a second spacer between the first spacer and the third spacer,
wherein the first spacer, the second spacer and the third spacer constitute the spacer structure.

23. The manufacturing method of claim 22, wherein after removing the part of the gate dielectric material layer on both sides of the gate, the gate dielectric material layer comprises a first portion with a larger thickness and a second portion with a smaller thickness, and the gate and the spacer structure is located on the first portion.

24. The manufacturing method of claim 22, wherein after removing the part of the gate dielectric material layer on both sides of the gate, the gate dielectric material layer comprises a first portion with a larger thickness and a second portion with a smaller thickness, the gate and the first spacer is located on the first portion, and the second spacer and the third spacer are located on the second portion.

25. The manufacturing method of claim 15, further comprising forming a contact electrically connected to the gate directly above a channel region of the transistor structure after forming the metal silicide layer.
